(19) United States
(12) Patent Application Publication
(10) Pub. No.: US 2007/0126462 A1
(43) Pub. Date: Jun. 7, 2007

(54) Enabling multiple memory modules for high-speed memory interfaces

(75) Inventor: Woong Hwan Ryu, El Dorado Hills, CA (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/294,848

(22) Filed: Dec. 5, 2005

(51) Int. Cl. H03K 19/003

(52) U.S. Cl. 326/30

(57) ABSTRACT

In some embodiments a memory module includes a first on-chip termination device and a second on-chip termination device coupled to the first on-chip termination device to obtain an input impedance that is frequency independent. Other embodiments are described and claimed.

### TECHNICAL FIELD

The inventions generally relate to enabling memory modules for high-speed memory interfaces.

### BACKGROUND

Synchronous Dynamic Random Access Memory (SDRAM) is a type of Dynamic Random Access Memory (DRAM) that has been widely used since the later part of the 1990s. SDRAM chips eliminate wait states because they are fast enough to be synchronized with the Central Processing Unit (CPU) clock. SDRAM chips are divided into two cell blocks, and data are interleaved between the two. While a bit in one block is accessed, a bit in the other is prepared for access. This allows SDRAM to perform at a fast rate.

Double Data Rate SDRAM (DDR) doubles transfer rates by transferring data on both the rising and falling edges of the clock. DDR2-SDRAM chips increase data rates using various techniques such as on-chip termination (ODT), which is a way to improve signal integrity of the memory channel. DDR2 memory chips support on-chip termination, allowing some motherboard ODT components to be integrated into the memory in order to eliminate excess signal noise on the memory chip.

However, as memory interfaces have increased in speed and it has become important to enable multiple memory modules for the high speed interfaces, inter-symbol interference (ISI) and input impedance have varied.

### BRIEF DESCRIPTION OF THE DRAWINGS

The inventions will be understood more fully from the detailed description given below and from the accompanying drawings of some embodiments of the inventions which, however, should not be taken to limit the inventions to the specific embodiments described, but are for explanation and understanding only.

FIG. 1 illustrates a multiple memory module system according to some embodiments of the inventions.

FIG. 2 illustrates various exemplary stub impedance profiles vs. frequency for various ODT arrangements of a memory module according to some embodiments of the inventions.

FIG. 3 illustrates an equivalent circuit model of a system according to some embodiments of the inventions.

FIG. 4 illustrates voltage transfer functions according to some embodiments of the inventions.

FIG. 5, including FIG. 5A and FIG. 5B, illustrates measured on-chip termination sensitivity in the time domain according to some embodiments of the inventions.

FIG. 6 illustrates voltage transfer functions according to some embodiments of the inventions.

FIG. 7 illustrates voltage transfer functions according to some embodiments of the inventions.

### DETAILED DESCRIPTION

Some embodiments of the inventions relate to enabling memory modules for high-speed memory interfaces.

In some embodiments a memory module includes a first on-chip termination device and a second on-chip termination device coupled to the first on-chip termination device to obtain an input impedance that is frequency independent.

In some embodiments a system includes a first memory module and a second memory module. At least one of the memory modules includes a first on-chip termination device and a second on-chip termination device coupled to the first on-chip termination device to obtain an input impedance that is frequency independent.

In some embodiments a memory module on-chip termination value on the memory module is minimized to obtain an input impedance that is frequency independent.

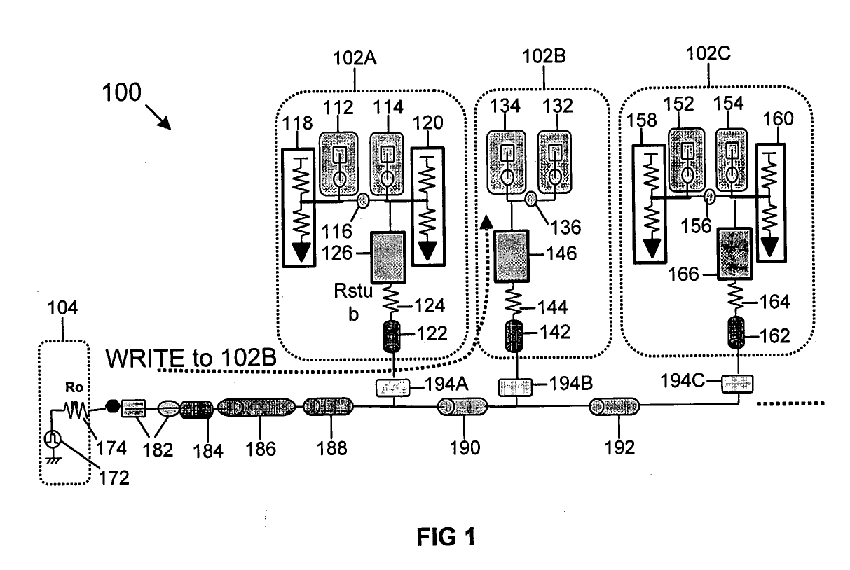

FIG. 1 illustrates a system 100 including a plurality of memory modules 102A, 102B, 102C, and a memory controller 104. Although three memory modules 102A, 102B, and 102C are illustrated in FIG. 1, any number of memory modules may be included in a system according to some embodiments, as illustrated by the . . . near the bottom right side of memory module 102C. Dotted line 106 shows an exemplary write operation to memory module 102B, for example. In some embodiments some or all of the memory modules (for example, memory modules 102A, 102B, and 102C) are Dual In-line Memory Modules (DIMMs). Memory module 102A includes a memory device 112 (for example, a top memory device), a memory device 114 (for example, a bottom memory device), a via through-hole 116, a first on-chip termination (ODT) circuit 118, a second on-chip termination (ODT) circuit 120, a trace 122, a resistor (Rstub) 124, and an impedance transformer 126. The second ODT circuit 120 is connected in parallel with first ODT circuit 118 to help lower the impedance (for example, cut it in half). Memory module 102B includes a memory device 132 (for example, a top memory device), a memory device 134 (for example, a bottom memory device, a via through-hole 136, a trace 142, a resistor 144, and an impedance transformer 146. Since some memory arrangement such as DDR2 used dynamic termination between the memory modules (that is, a memory device is “open” when reading or writing and ODT does not occur) memory module 102B is shown without ODT since FIG. 1 is illustrating a write operation to memory module 102B. Memory module 102C includes a memory device 152 (for example, a top memory device), a memory device 154 (for example, a bottom memory device), a via through-hole 156, a first on-chip termination (ODT) circuit 158, a second on-chip termination (ODT) circuit 160, a trace 162, a resistor 164, and an impedance transformer 166. Memory controller 104 includes a voltage driver 172 and a driver resistor 174. Memory controller 104 is coupled to the memory modules 102A, 102B, 102C, etc. via a chipset package 182, a breakout trace 184, a main trace 186, a high impedance narrow break-in trace 188, traces 190 and 192 between memory modules (typically on a board such as a memory board), and connectors 194A, 194B, and 194C to memory modules 102A, 102B, and 102C, respectively.

According to some embodiments frequency independent input impedance of a raw card stub is obtained. In some embodiments frequency independent input impedance is obtained by lowering on-chip termination at a memory module (for example, a Synchronous Dynamic Random Access Memory or SDRAM). In some embodiments ODT at the memory module (for example, SDRAM) is cut in half using a second ODT circuit that is on and in parallel with a first ODT circuit (for example, lowering ODT to approximately 25 ohms using a first and second ODT of 50 ohms each that are in parallel with each other, and/or for example 2R 2R, 1R 2R & 2R 1R (WRITE to 1R)). It is noted that 2R==2 rank, 1R==1 rank, so, for example, 2R 1R configuration means the system has 2 rank at the first memory module (for example, DIMM) and 1 rank at the second memory module (for example, DIMM). In some embodiments a second 50 ohm ODT device is used as a dummy active device, for example (1R 1R, 1R 2R, & 2R 1R (WRITE to 2R)). In some embodiments single and/or multiple impedance transformers using a transmission line are used to obtain frequency independent input impedance. In some embodiments a resistor (for example, an Rstub resistor) is used to increase DC gain to obtain frequency independent input impedance.

In some embodiments frequency independent input impedance may be obtained at a Chip on Board (COB) level. In some embodiments frequency independent input impedance may be obtained at a memory module level (for example, a dual in-line memory module or DIMM level for multi-drop interfaces). In some embodiments frequency independent input impedance may be obtained at a package level. In some embodiments frequency independent input impedance may be obtained at a chip level. In some embodiments frequency independent input impedance may be obtained in an application to a differential interface and in some embodiments frequency independent input impedance may be obtained in an application to single ended interfaces (for example, DDR2 and/or DDR3).

In some embodiments by using frequency independent input impedance of a raw card stub, a frequency independent interconnect system characteristic and/or maximization of interconnect network bandwidth may be obtained. In some embodiments an increased number of memory modules (for example, DIMMs or SDRAM devices) may be implemented.

In some embodiments a cost effective and/or flexible design is implemented by lowering ODT and/or by changing the length and the width of the transmission line (for example, as an impedance transformer) considering target frequency. For example, the fundamental and third harmonic frequency may be changed to change the digital frequency of the signal. In some embodiments an improved noise and timing margin may be obtained. In some embodiments a cost effective and/or flexible design is implemented by using a second ODT that is turned on, and/or by changing the width and/or length of a transmission line to use it as an impedance transformer, and/or to consider target frequency.

In some embodiments a frequency independent stub input impedance may be obtained using one or more of the following:
Lowering ODT at the memory module (for example using low single ODT or a second ODT circuit). For example, the second ODT may be 50 ohms that is on for 2R 2R, 1R 2R, AND 2R 1R (WRITE to 1R) implementations;
Lowering ODT at the memory module (for example using low single ODT or a second ODT circuit). For example, the second ODT may be 50 ohms that is on as a dummy active device for 1R 1R, 1R 2R, and 2R 1R (WRITE to 2R);
Single or multiple sections of impedance transformers using an interconnection line (or lines); and/or
An Rstub resistor to increase DC gain.

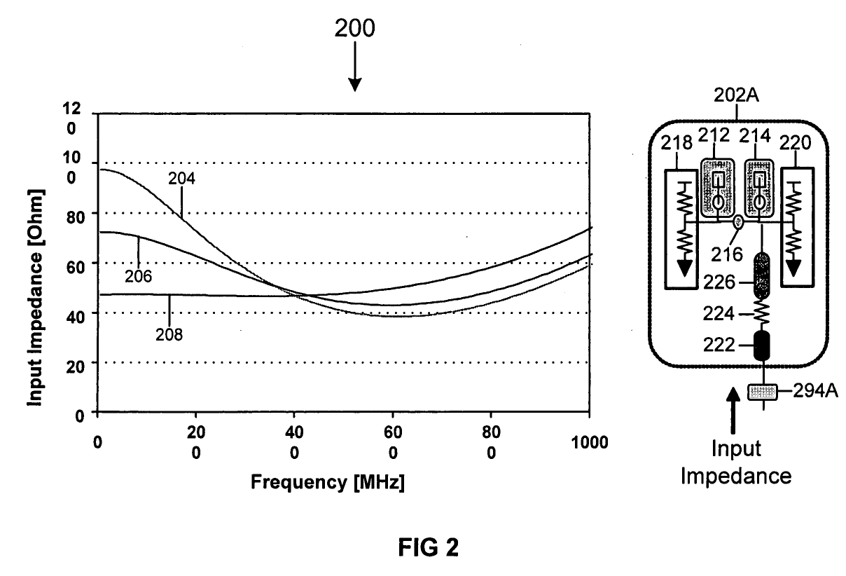

In some embodiments as illustrated in FIG. 1, multiple memory modules (for example, multiple DIMMs per channel or DIMMs/CH), low ODT values, a transmission line transformer, and/or Rstub may all be used. In some embodiments a frequency independent impedance profile may be maintained up to a high frequency (for example 500 MHz) by using low impedance on-chip transmission (for example, in some embodiments ODT of 50 ohms in parallel with 50 ohms for an effective resistance of 25 ohms), and/or a TL1 line (for example of approximately one inch) may be used as an impedance transformer. This can help make Cdie insensitive in the frequency domain (FD) and provides better impedance transforming, for example, as illustrated in FIG. 2.

FIG. 2 illustrates various exemplary stub impedance profiles 200 vs. frequency for various ODT arrangements of a memory module 202A. Memory module 202A includes a memory device 212 (for example, a top memory device), a memory device 214 (for example, a bottom memory device), a via through-hole 216, a first on-chip termination (ODT) circuit 218, a second on-chip termination (ODT) circuit 220, a trace 222, a resistor (Rstub) 224, and an impedance transformer 226. A connector 294A to memory module 202A is also illustrated in FIG. 2. Impedance profiles 200 include a profile 204 in which ODT is equal to 75 ohms (for example, as proposed by the original JEDEC standard), a profile 206 in which ODT is equal to 50 ohms, and a profile 208 in which ODT is equal to two 50 ohm resistances in parallel (equating to 25 ohms) (for example, ODT circuit 218 and ODT circuit 220 each having values of 50 ohms). As illustrated in FIG. 2 the profile 208 with a lower effective impedance of 25 ohms by adding a second ODT of 50 ohms to a typical 50 ohm ODT circuit helps to ensure an input impedance that is frequency independent. This can help to maximize bandwidth and minimize ISI (inter-symbol interference). As illustrated in FIG. 2, profile 208 shows input impedance that is frequency independent, particularly at frequencies up to around 500 MHz and beyond.

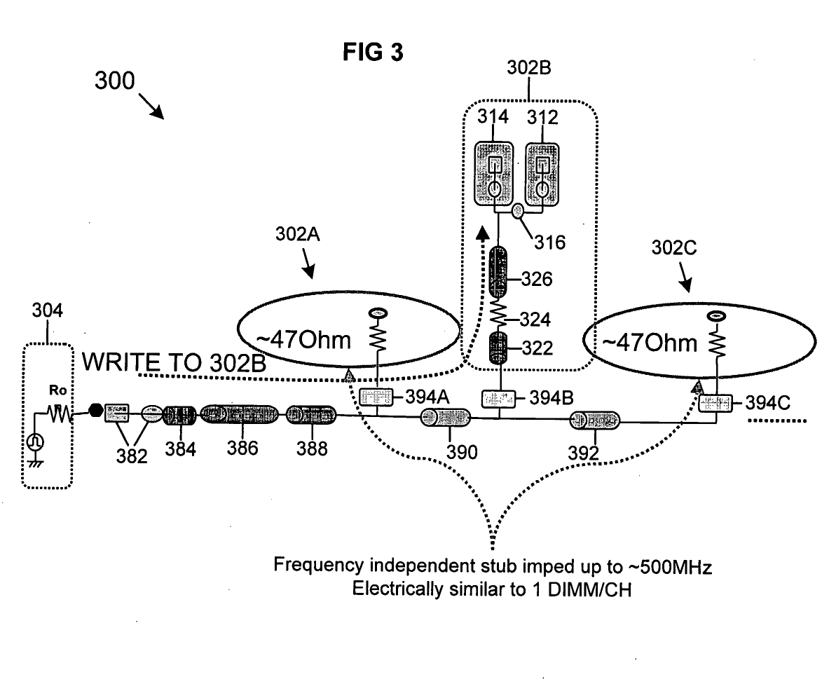

FIG. 3 illustrates an equivalent circuit model of a system 300 according to some embodiments (for example, in some embodiments an equivalent circuit model up to approximately 500 MHz, or more than 500 MHz). System 300 shows how the system is electrically similar to one memory module per channel (for example, DIMM per channel) using multiple memory modules per channel (for example, multiple DIMMs per channel) at frequencies up to 500 MHz and beyond. System 300 includes a memory module 302B that includes a memory device 312 (for example, a top memory device), a memory device 314 (for example, a bottom memory device), a via through-hole 316, a trace 322, a resistor (Rstub) 324, and an impedance transformer 326. In some embodiments, for example, the resistance value Rstub of resistor 324 is approximately 22 ohms. A memory module 302A, 302C, . . . , etc. are illustrated to show that they provide an impedance (for example, in some embodiments, approximately 47 ohms) when a WRITE to memory module 302B is occurring. System 300 also includes a memory controller 304 that is coupled to the memory modules 302A, 302B, 302C, etc. via a chipset package 382, a breakout trace 384, a main trace 386, a high impedance narrow break-in trace 388, traces 390 and 392 between memory modules (typically on a board such as a memory board), and connectors 394A, 394B, and 394C to memory modules 302A, 302B, and 302C, respectively. FIG. 3 illustrates how frequency independent input impedance is obtained according to some embodiments. In some embodiments a system with dynamic termination of memory modules provides frequency independent input impedance at high frequencies (for example up to approximately 500 MHz or more).

In some embodiments frequency independent input impedance may be maintained for memory interface products including single ended or differential memory arrangements (for example, DDR2 and/or DDR3 and/or future memory implementations) with multiple memory modules (for example, DIMMs) per channel. In some embodiments DDR system bandwidth is significantly improved.

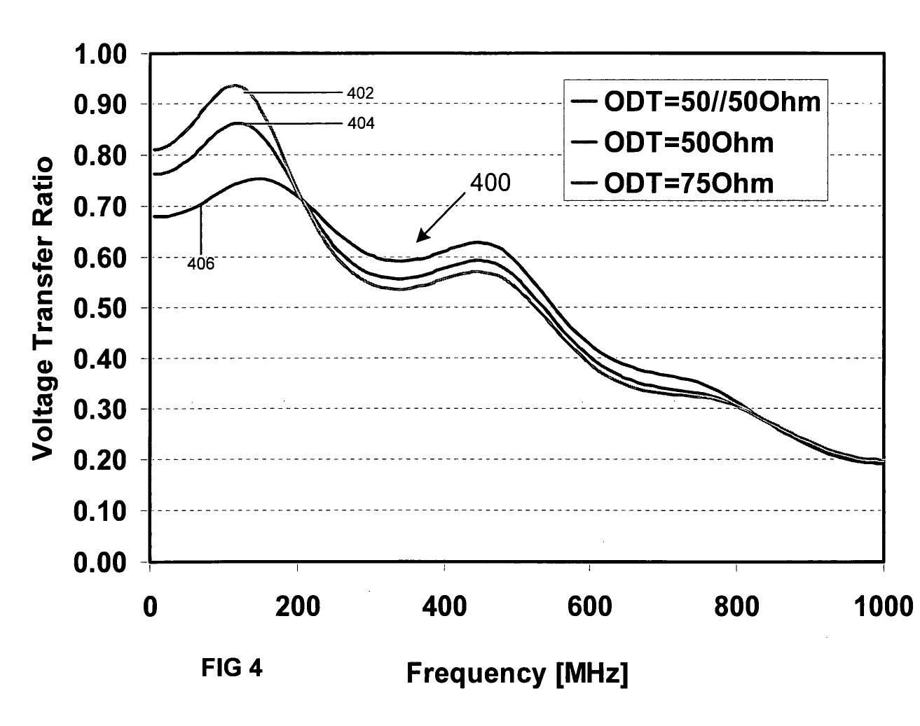

FIG. 4 illustrates write-mode frequency domain voltage transfer functions 400 (voltage transfer ratio) of a two memory module per channel (DIMM/CH) with 2Rank 2Rank configuration (2R 2R). Line 402 represents a voltage transfer function of a single 75 ohm ODT implementation (for example, as proposed in the original JEDEC spec), line 404 represents a voltage transfer function of a single 50 ohm ODT implementation, and line 406 represents a voltage transfer function in which a memory module (for example, SDRAM) includes a first 50 ohm ODT and a second 50 ohm ODT that are connected in parallel, and also includes an impedance transformer (of approximately one inch) using a transmission line. The line 406 with a first 50 ohm ODT and a second 50 ohm ODT on shows enough voltage margin and the best signal quality (SQ). As illustrated in FIG. 4, DDR800 is possible and even DDR1066 and beyond are feasible in terms of system bandwidth, adequate voltage margin and best SQ. In some embodiments, an additional second active ODT device is used for 1R DIMM to enhance input impedance frequency independence of current DDR2 products currently in use.

In some embodiments of two DIMM populated DDR systems (for example a 1R 2R implementation with a second active ODT device becomes better than a one DIMM populated DDR system such as a 2R NC implementation). In some embodiments more DIMMs per channel memory platforms will be able to be supported. For instance, DDR800+ 2DIMM/CH 4 ranks can be supported for desktop implementations with registered DIMM (to fix address/control (ADDR/CNTL) limit, and DDR800+ 3DIMM/CH 6 ranks can be supported for server implementations with registered DIMM, DDR3 registered DIMM, and future multi-rank differential implementations.

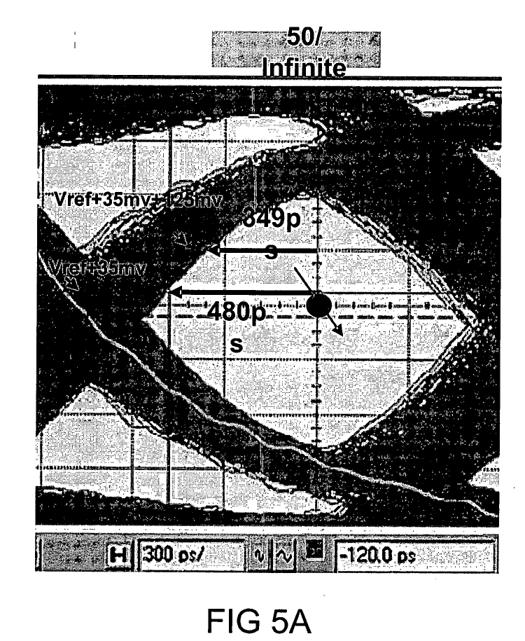

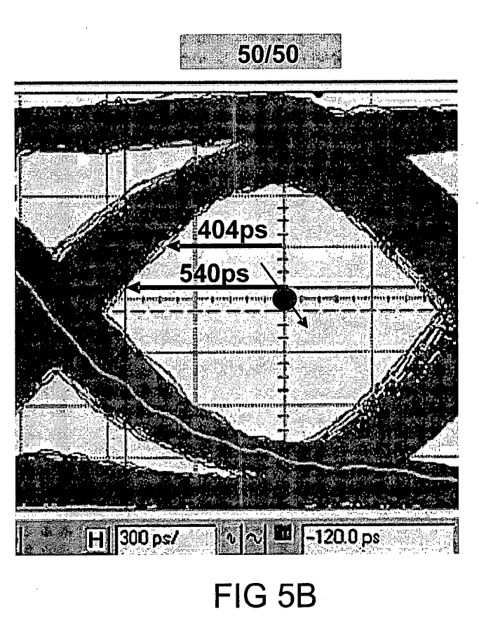

FIG. 5 (including FIG. 5A and FIG. 5B) illustrate measured ODT sensitivity vs. time (nsec) for WRITE frequency domain (FD) voltage transfer function of 2 DIMM/CH 2R 2R. FIG. 5A illustrates a single 50 ohm implementation, and FIG. 5B illustrates an implementation of a first 50 ohm ODT and a second 50 ohm ODT in parallel according to some embodiments.

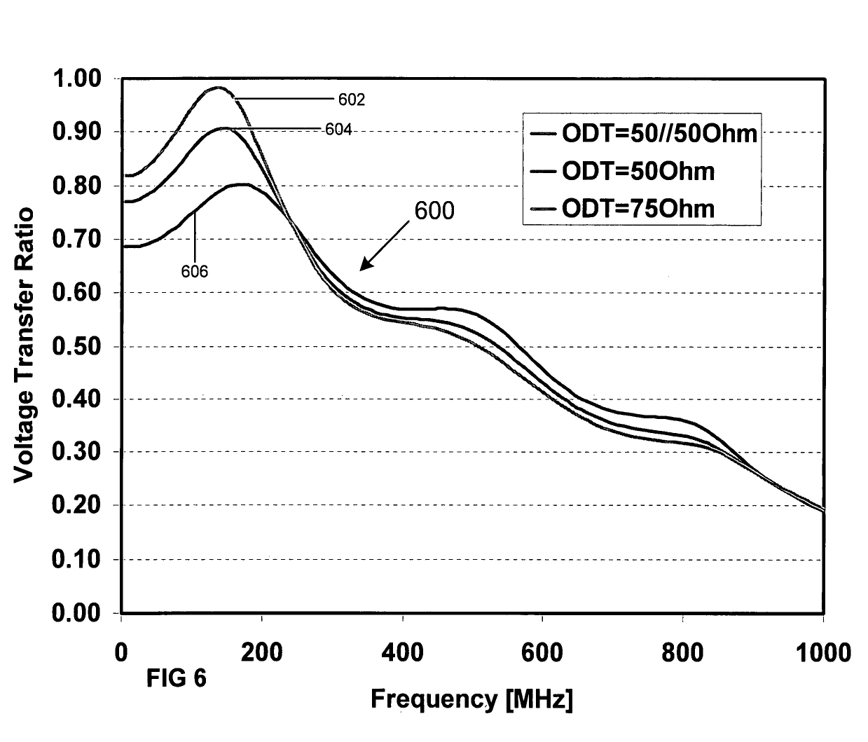

FIG. 6 illustrates a graphic representation 600 of a WRITE FD (frequency domain) voltage transfer function (voltage transfer ratio) of a 1R 2R (WRITE to 2R) implementation. Line 602 represents a voltage transfer function of a single 75 ohm ODT implementation (for example, as proposed in the original JEDEC spec), line 604 represents a voltage transfer function of a single 50 ohm ODT implementation, and line 606 represents a voltage transfer function in which a memory module (for example, SDRAM) includes a first 50 ohm ODT and a second 50 ohm ODT that are connected in parallel according to some embodiments.

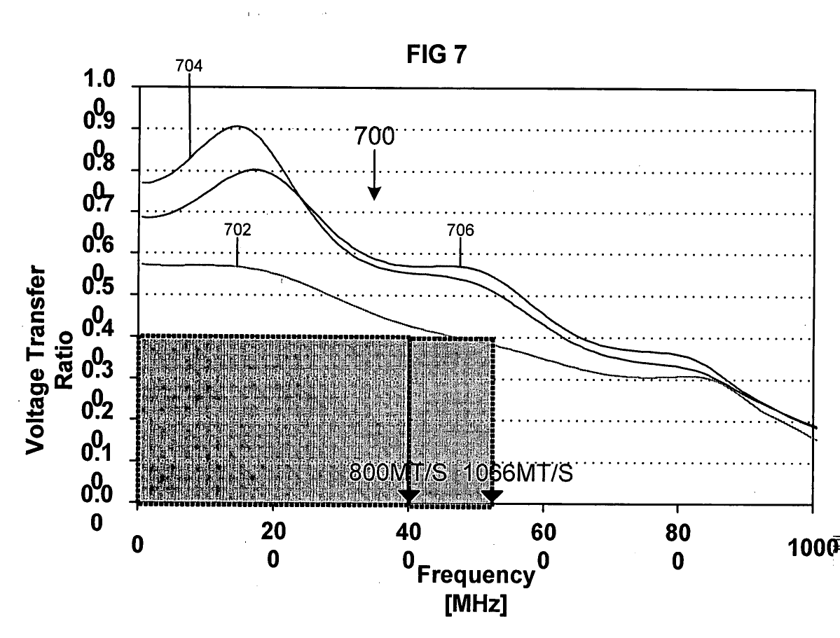

FIG. 7 illustrates a graphic representation 700 of a WRITE FD (frequency domain) voltage transfer function (voltage transfer ratio) of a 2 DIMM/CH 1R 2R implementation. Line 702 represents a voltage transfer function of a 2R NC 75 ohm ODT implementation, line 704 represents a voltage transfer function of a single 50 ohm ODT implementation, and line 706 represents a voltage transfer function in which a memory module includes a first 50 ohm ODT and a second 50 ohm ODT that are connected in parallel according to some embodiments.

In some embodiments a low ODT is used (for example, by turning on a second ODT, for example, in a DDR2 implementation), an impedance transformer is included in the memory module (for example, by increasing the width and/or length of a transmission line), and/or an Rstub resistor can be included. In some embodiments such a low ODT, impedance transformer, and/or Rstub resistor are used to minimize SDRAM/DIMM loading impact and improve bandwidth. This can help enable DDR2 800 and beyond with multiple DIMM/CH platforms with a cost effective solution and a short development time period.

In some embodiments a high frequency RF (radio frequency) and microwave technique are applied to DDR buses to minimize return loss from loaded DIMMs and maximize the interconnect network bandwidth. For example, a 70 ps timing and 100 mV noise margin improvement can be obtained in a DDR2 implementation.

Although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Some embodiments may be implemented in one or a combination of hardware, firmware, and software. Some embodiments may also be implemented as instructions stored on a machine-readable medium, which may be read and executed by a computing platform to perform the operations described herein. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other form of propagated signals (e.g., carrier waves, infrared signals, digital signals, the interfaces that transmit and/or receive signals, etc.), and others.

An embodiment is an implementation or example of the inventions. Reference in the specification to “an embodiment,” “one embodiment,” “some embodiments,” or “other embodiments” means that a particular feature, structure, or characteristic described in connection with the embodiments is included in at least some embodiments, but not necessarily all embodiments, of the inventions. The various appearances “an embodiment,” “one embodiment,” or “some embodiments” are not necessarily all referring to the same embodiments.

If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

Although flow diagrams and/or state diagrams may have been used herein to describe embodiments, the inventions are not limited to those diagrams or to corresponding descriptions herein. For example, flow need not move through each illustrated box or state, or in exactly the same order as illustrated and described herein.

The inventions are not restricted to the particular details listed herein. Indeed, those skilled in the art having the benefit of this disclosure will appreciate that many other variations from the foregoing description and drawings may be made within the scope of the present inventions. Accordingly, it is the following claims including any amendments thereto that define the scope of the inventions.

What is claimed is:

1. A memory module comprising:
a first on-chip termination device;
a second on-chip termination device coupled to the first on-chip termination device to obtain an input impedance that is frequency independent.

2. The memory module of claim 1, further comprising an impedance transformer to obtain the input impedance that is frequency independent.

3. The memory module of claim 2, further comprising a stub resistor to obtain the input impedance that is frequency independent.

4. The memory module of claim 1, wherein the memory module is a DIMM.

5. The memory module of claim 1, wherein the memory module is a dynamic termination memory module.

6. The memory module of claim 1, wherein the memory module is a DDR memory module.

7. The memory module of claim 6, wherein the memory module is a DDR2 memory module.

8. The memory module of claim 6, wherein the memory module is a DDR3 memory module.

9. The memory module of claim 1, wherein the memory module is a single ended interface memory module.

10. The memory module of claim 1, wherein the memory module is a differential ended interface memory module.

11. The memory module of claim 1, wherein the memory module is a high speed interface memory module.

12. The memory module of claim 1, wherein the input impedance is frequency independent to at least 500 MHz.

13. The memory module of claim 1, wherein the second on-chip termination device is coupled in parallel with the first on-chip termination device.

14. A system comprising:
a first memory module; and
a second memory module including a first on-chip termination device and a second on-chip termination device coupled to the first on-chip termination device to obtain an input impedance that is frequency independent.

15. The system of claim 14, the second memory module further including an impedance transformer to obtain the input impedance that is frequency independent.

16. The system of claim 14, wherein the memory modules are dynamic termination memory modules.

17. The system of claim 14, wherein the first and second memory modules are single ended interface memory modules.

18. The system of claim 14, wherein the first and second memory modules are differential ended interface memory modules.

19. The system of claim 14, wherein the memory modules are high speed interface memory modules.

20. The system of claim 14, wherein the input impedance is frequency independent to at least 500 MHz.

21. The system of claim 14, wherein the second on-chip termination device is coupled in parallel with the first on-chip termination device.

22. A method comprising:
minimizing a memory module on-chip termination value on a memory module to obtain an input impedance that is frequency independent.

23. The method of claim 22, wherein the input impedance is frequency independent to at least 500 MHz.
